(19) United States
(12) Patent Application Publication
(10) Pub. No.: US 2008/0107820 A1
(43) Pub. Date: May 8, 2008

(54) Deposition Rate Plasma Enhanced Chemical Vapor Process

(76) Inventors: Aaron M. Gabelnick, Ithaca, NY (US); Christina A. Lambert, Midland, MI (US)

Correspondence Address: The Dow Chemical Company, Intellectual Property Section, P.O. Box 1967, Midland, MI, 48641-1967, US

(21) Appl. No.: 11/664,455

(22) PCT Filed: Oct. 19, 2005
(86) PCT No.: PCT/US05/37435

§ 371 Date: Apr. 2, 2007

Related U.S. Application Data
(60) Provisional application No. 60/623,691, filed on Oct. 29, 2004.

(51) Int. Cl. C23C 16/513

(52) U.S. Cl. 427/489

(57) ABSTRACT

A process for depositing a layer of a plasma polymerized organosiloxane, siloxane or silicon oxide onto the surface of an organic polymeric substrate by atmospheric pressure glow discharge deposition from a gaseous mixture comprising a silicon containing compound and an oxidant, characterized in that the oxidant comprises N₂O.

### BACKGROUND OF THE INVENTION

The present invention relates to coating or modifying a substrate using plasma enhanced chemical vapor deposition (PECVD), also referred to as glow discharge chemical vapor deposition, under atmospheric pressure or near atmospheric pressure conditions.

It is previously known to modify the surface of polymers such as polyolefins having an undesirably low surface energy in order to improve the surface wettability or adhesion or both, through deposition of a silicon oxide layer. Other polymers, such as polycarbonate have been similarly modified in order to provide improved chemical resistance, enhanced gas barrier, adhesion, antifog properties, abrasion resistance, static discharge, or altered refractive index.

U.S. Pat. No. 5,576,076 taught that the wettability and adhesion properties of polyolefin film can be improved by creating a deposit of a silicon oxide compound by subjecting the substrate to corona discharge at atmospheric pressure in the presence of a silane, a carrier gas, and an oxidant. U.S. Pat. No. 5,527,629 taught a similar process wherein oxygen in the form of residual air was present during the corona discharge treatment. Disadvantageously, the preferred silane in both processes, SiH₄, is readily oxidized, thereby requiring careful attention to prevent fires or the formation of silicon oxide particles.

U.S. Pat. No. 6,106,659 describes a cylinder-sleeve electrode assembly apparatus that generates plasma discharges in either an RF resonant excitation mode or a pulsed voltage excitation mode. The apparatus is operated at a rough vacuum with working gas pressures ranging from about 10 to about 760 Torr (1-100 kPa). Suitable compounds for use in the treatment included inert gases like argon, nitrogen and helium; oxidants such as oxygen, air, NO, N₂O, NO₂, N₂O₄, CO, CO₂ and SO₂; and treating compounds such as sulfur hexafluoride, tetrafluoromethane, hexafluoroethane, perfluoropropane, acrylic acid, silanes and substituted silanes, like dichlorosilane, silicon tetrachloride, and tetraethylorthosilicate.

U.S. Pat. No. 5,718,967 disclosed a process operating at reduced pressures for treating an organic polymer substrate such as polycarbonate to provide coatings by PECVD using one or more organosilicon compounds, including silanes, siloxanes and silazanes, especially tetramethyldisiloxane (TMDSO), and oxygen containing balance gases. Adhesion promoting layers formed by plasma polymerization of an organosilicon compound in the absence or substantial absence of oxygen are first prepared followed by a protective coating layer formed in the presence of a higher level of oxygen, preferably a stoichiometric excess of oxygen. Similar disclosures of processes and apparatus for use in these processes are contained in U.S. Pat. Nos. 5,298,587, 5,320,875 and 5,433,786.

In WO2003/066932, published Aug. 14, 2003, there was disclosed a corona discharge process for surface modification of a polymer substrate, especially polycarbonate or polypropylene, employing volatile silicone compounds. In Example 4, a two step deposition of an adhesive organosilicon layer using tetramethyldisiloxane (TMDSO), followed by deposition of a monolithic silicon oxide layer using tetraethylorthosilicate (TEOS) was disclosed. The oxidant employed in both steps was air.

Jin-Kyung Choi et al., Surface and Coatings Technology, 131(1-3), pg. 136-140 (2000) disclosed that use of N₂O oxidant in a vacuum PECVD process which resulted in increased deposition rates of silicon dioxide coatings. A similar increase in deposition on the surface of Fe₂O₃ particles was observed by T. Mori, et al., Symposium on Plasma Science for Materials 8^{th} 51-5 (1995). Ward, et al., Langmuir, 19, 2110-2114 (2003) disclosed certain polymeric siloxane coatings prepared by atmospheric PECVD techniques.

### SUMMARY OF THE INVENTION

The present invention provides a process for depositing a layer of a plasma polymerized organosilicon, siloxane or silicon oxide onto the surface of an organic polymeric substrate by atmospheric pressure glow discharge deposition of a gaseous mixture comprising a silicon containing compound and an oxidant, characterized in that the oxidant comprises N₂O.

By using N₂O as the oxidant in place of at least some amount of oxygen or air, it has been discovered that increased deposition rates of the plasma polymerized product can be achieved without loss of coating properties. Highly desirably, the resulting organosilicon, siloxane or silicon oxide film is optically clear, homogeneous, monolithic, and highly adherent to the polymeric substrate, even without prior chemical or physical pretreatment of the substrate surface.

In a preferred embodiment, the deposited layer is an organosilicon compound and may serve as an adhesive layer for a multiple layer coating, which due to the fact that the resulting polymer is highly hydrophobic (oleophilic) and closely matches the surface properties of the organic polymer substrate, provides improved adhesion of the resulting multiple layer film. Moreover, the composition includes increased hydroxyl content and decreased crosslink density compared to prior art compositions, thereby simultaneously providing increased bonding strength to more polar organic polymers such as polycarbonate and acrylate or methacrylate based polymers and improved flexibility and elongation. Alternatively, the layer (or the second layer of a multilayer film) is a polymeric siloxane or silicon oxide compound that also is optically clear, homogeneous and monolithic, and which substantially lacks organic moieties, resulting in greater hydrophilicity, thereby imparting improved chemical resistance, increased gas permeability, greater static dissipation, altered refractive index, and greater hardness, toughness and abrasion resistance to the coated substrate. The process of the invention allows for increased deposition rates under atmospheric plasma deposition conditions, thereby allowing for a more economical process.

### BRIEF DESCRIPTION OF DRAWINGS

FIG. 1 is an illustration of a suitable apparatus used in the atmospheric pressure glow discharge deposition process.

### DETAILED DESCRIPTION OF THE INVENTION

For purposes of United States patent practice, the contents of any patent, patent application, or publication referenced herein are hereby incorporated by reference in their entirety (or the equivalent US version thereof is so incorporated by reference) especially with respect to the disclosure of synthetic techniques, raw materials, and general knowledge in the art. Unless stated to the contrary, implicit from the context, or customary in the art, all parts and percents are based on weight.

If appearing herein, the term “comprising” and derivatives thereof is not intended to exclude the presence of any additional component, step or procedure, whether or not the same is disclosed herein. In order to avoid any doubt, all compositions claimed herein through use of the term “comprising” may include any additional additive, adjuvant, or compound, unless stated to the contrary. In contrast, the term, “consisting essentially of” if appearing herein, excludes from the scope of any succeeding recitation any other component, step or procedure, excepting those that are not essential to operability. The term “consisting of”, if used, excludes any component, step or procedure not specifically delineated or listed. The term “or”, unless stated otherwise, refers to the listed members individually as well as in any combination.

As used herein the term “monolithic” refers to a solid layer substantially lacking in fissures, cracks and pits. Highly desirably, the solid lacks deformities extending greater than 10 percent of the thickness of the solid layer from the surface. The term “substantially uniform” refers to a solid layer having a mean thickness greater than or equal to 80 percent of the maximum thickness and lacking deformities extending greater than 25 percent of the thickness of the solid layer from the surface. The term “silicon oxide” refers to compounds containing at least some silicon oxygen bonds including polymeric silicon oxides containing less than a stoichiometric quantity of oxygen. The term “organosilicon compound” refers to compounds containing both silicon and one or more aliphatic, cycloaliphatic or aromatic groups bonded directly to the silicon or through one or more oxygen, nitrogen or other noncarbon atoms. It is to be understood by the skilled artisan, that the formulas of the organosilicon and polymeric siloxane or silicon oxide film compositions prepared herein are empirical formulas and not molecular formulas.

The term “highly adherent” or “adhesive layer” refers to a organosilicon film deposited onto an organic polymeric substrate, optionally in combination with a polymeric siloxane or silicon oxide surface layer, which multilayer composition does not show loss of anticondensation properties, delamination or loss from the substrate surface when exposed to boiling water at a distance of 10 cm from the surface of the boiling water for at least three minutes, preferably at least 10 minutes. Highly desirably, the organic polymeric substrate comprises a polycarbonate, polyethylene-terephthalate (PET), polystyrene, a polyolefin, or a polyC₁₋₈alkyl(meth)acrylate polymer. The term “polymer” or “polymeric” refers to homopolymers and copolymers, including block or random copolymers, of any molecular weight or chain branching configuration.

Any suitable apparatus for performing atmospheric pressure plasma deposition of the silicone compound can be employed in the present invention. Examples include those devices previously disclosed in U.S. Pat. No. 5,433,786, WO2003/066933, Ward et al., Langmuir, 2003 19, 2110-2114, and elsewhere. In all of the foregoing apparatuses, the organosilicon reagent compound is supplied as a vapor to a flowing stream of a gas (carrier gas) in the vicinity of an electrode, preferably by passing through or over the surface of the electrode, where a plasma is produced by electrical discharge between the electrode and a counter electrode. The amount of organosilicon reagent compound may be increased by use of heating to increase the vapor pressure thereof or by atomization using, for example, an ultrasonic atomizer. The latter method for achieving sufficient vapor pressure of the organosilicon reagent compound is preferred due to the avoidance of elevated temperatures that may approach the autoignition temperature of the gaseous mixture. Although the process is referred to as operating at atmospheric pressure, it is to be understood that pressures slightly above or below atmospheric (±20 kPa) are operable as well. Preferably the operating pressure is atmospheric or sufficiently above atmospheric pressure as needed to obtain the desired gas flow past the electrode(s).

Suitable silicon containing reagent compounds for use herein include silicone compounds, especially organosiloxanes. The term “silicone compound” as used herein refers to compounds containing both silicon-carbon bonds and silicon-oxygen bonds. Desirably, the compounds possess a suitable vapor pressure such that a sufficient quantity of the compound can be included in the carrier gas without use of excessive heat to volatilize the silicon containing compound thereby approaching the autoignition temperature of the mixture. Preferred organosilicon reagent compounds for use herein include compounds of the formula: R₄Si[OSi(R′)₂]ᵣ, wherein R and R′, independently each occurrence, are hydrogen, hydroxyl, C₁₋₁₀ hydrocarbyl, or C₁₋₁₀ hydrocarbyloxy, and r is a number from 0 to 10. Preferred organosilicon reagent compounds correspond to the formula: H₂Si(R″₂)OSi(R′)₂, HₛSi(OR″)₄₋ₛ or (R″O)₃Si[OSi(OR″)₂]ₜOH, wherein R″, independently each occurrence is C₁₋₄ hydrocarbyl, preferably C₁₋₄ alkyl, most preferably methyl or ethyl, and s and t independently each occurrence are numbers from 0 to 4. Highly preferred organosilicon reagent compounds are tetraC₁₋₄alkyldisiloxanes and tetraC₁₋₄alkylorthosilicates, especially tetramethyldisiloxane and tetraethylorthosilicate. Most preferred silicon containing compounds include linear and cyclic organosiloxanes such as tetraalkyldisiloxanes, hexaalkyldisiloxanes, tetraalkylcyclotetrasiloxanes and octaalkylcyclotetrasiloxanes. A most highly preferred silicon containing compound for use as a reagent herein is tetramethyldisiloxane.

Sufficient N₂O oxidant is provided in the form of a balance gas which may be mixed with the carrier gas prior to entry into the reactor or added separately to the reactor, to produce the desired product, that is an organosiloxane compound or by increasing the oxidant concentration, a siloxane or silicon oxide. Additional components of the gaseous mixture include inert substances such as nitrogen, helium, argon, and carbon dioxide. Small quantities of additional oxidants such as O₂, O₃, NO, NO₂, N₂O₃ and N₂O₄ may be included in the oxidant mixture without departing from the scope of the invention, however, substantially pure N₂O is the most preferred oxidant. Most preferably, the carrier gas is nitrogen and the working gas is a mixture of nitrogen and N₂O. Desirably, the quantity of silicon containing compound present in the gaseous mixture is maintained in the range from at least 600 ppm, preferably at least 2000 ppm, and more preferably at least 3500 ppm; and not greater than 10000 ppm, preferably not greater than 8000 ppm, and more preferably not greater than 7000 ppm. Reduced quantities of silicon containing compound result in reduced rates of coating deposition while elevated levels can result in gas phase nucleation which can cause poor film quality and even powder formation in the coating.

Highly desirably, the first layer contains residual organic and/or polar functionality such as hydroxyl or hydrocarbyloxy functionality. Desirably, such functionality, comprises from 0.1 to 10 mol percent of the adhesive polymer layer. The resulting product is also believed to be less highly cross-linked than a more fully oxidized layer, thereby imparting better flexibility to the coated layer. The first layer imparts improved adhesion properties in a multiple layer film construction. Moreover, the second layer, and to some extent the first layer, desirably comprise a small but less than stoichiometric quantity of nitrogen, for example, in the form of silicon nitride functional groups.

In the process of the present invention, sufficient power density and frequency are applied to an electrode/counter electrode pair to create and maintain a glow discharge in a spacing between the electrode and counter electrode. The power density (based on electrode surface area exposed to the plasma) is preferably at least 1 W/cm², more preferably at least 5 W/cm², and most preferably at least 10 W/cm²; and preferably not greater than 200 W/cm², more preferably not greater than 100 W/cm², and most preferably not greater than 50 W/cm². The frequency is preferably at least 2 kHz, more preferably at least 5 kHz, and most preferably at least 10 kHz; and preferably not greater than 100 kHz, more preferably not greater than 60 kHz, and most preferably not greater than 40 kHz. The current applied to the electrodes may vary from 10 to 10,000 watts, preferably from 100 to 1000 watts, at potentials of 10 to 50,000 volts, preferably 100 to 20,000 volts.

The spacing between electrode and counter-electrode is sufficient to achieve and sustain a visible plasma (glow discharge), preferably at least 0.1 mm, more preferably at least 1 mm, and preferably not more than 50 mm, more preferably not more than 20 mm, and most preferably not more than 10 mm. The electrode, the counter electrode or both the electrode and the counter electrode may be fitted with a dielectric sleeve, if desired. In one embodiment, the electrode and counter electrode pair are encased within a high temperature resistant dielectric, such as a ceramic. The substrate to be coated may be supported or transported by the counter electrode or other wise supported in the vicinity of the plasma in order to be contacted or impinged by at least a portion of the plasma generated by the electrode and counter electrode. For the purposes of this invention, the terms electrode and counter electrode are used to refer to a first electrode and a second electrode, either of which can be polarized with the other being oppositely polarized or grounded. The flow of the carrier gas/balance gas together with the plasma generated in the vicinity of the electrodes causes plasma polymerized product to be deposited onto the surface of the substrate attached to the counter electrode or placed in the vicinity of an electrode pair. A suitable gap is provided between the substrate and the electrode or electrodes for exhaust of the carrier gas, by-products and unattached products. The width of the gap is adjusted to prevent incursion of excess amounts of contaminating gases, especially air.

Preferably the velocity of the total gas mixture through the electrode or electrode pair(s) is such that a stable plasma is formed allowing for uniform deposition of polymerized product. Desirably, the velocity of the gas passing through the exit ports is at least about 0.05 m/s, more preferably at least about 0.1 m/s, and most preferably at least about 0.2 m/s; and preferably not greater than about 1000 m/s, more preferably not greater than about 500 m/s, and most preferably not greater than about 200 m/s.

As defined herein “electrode” refers to a single conductive element or a plurality of conductive elements spaced sufficiently apart within a reactor equipped with sufficient gas flow to form a stable plasma when energized. Preferably, the electrode is hollow or equipped with a conduit for supply of the working gas mixture through one or more openings in the surface thereof. Thus, the term “past the electrode” refers to gas flowing through one or more inlets in the vicinity of the single element or multiple elements, past or near to a surface of the counter electrode, and past or onto the substrate to be coated through one or more outlets. Advantageously, because of the foregoing gas flow in an atmospheric pressure plasma deposition process, ablated material from the electrode or the walls of the reactor, if any, is substantially evacuated, thereby resulting in reduced surface defects and improved planarity in the resulting film.

Plasma polymerization as carried out by the process of the present invention typically results in an optically clear coating deposited on the surface of the substrate. The term “optically clear” is used herein to describe a coating having an optical clarity of at least 70 percent, more preferably at least 90 percent, and most preferably at least 98 percent and a haze value of preferably not greater than 10 percent, more preferably not greater than 2 percent, and most preferably not greater than 1 percent. Optical clarity is the ratio of transmitted-unscattered light to the sum of transmitted-unscattered and transmitted-scattered light (<2.5°). Haze is the ratio of transmitted-scattered light (>2.5°) to total transmitted light. These values are determined according to ASTM D 1003-97.

The substrate used in the present invention includes organic polymers in any form. Examples of substrates include films, sheets, fibers, and woven or non-woven fabrics of thermoplastics, such as polyolefins including polyethylene, polypropylene, and copolymerized mixtures of ethylene, propylene, and/or a C₄₋₈ α-olefin, polystyrenes, polycarbonates, polyesters including polyethylene terephthalate, polylactic acid, and polybutylene terephthalate, polyacrylates, polymethacrylates, and interpolymers of any of the monomers employed in the foregoing polymers A preferred substrate is polycarbonate. By the term “film” with respect to the substrate, is meant any material of any desired length or width and having a thickness from 0.001 to 0.1 cm. By the term “sheet” is meant a substrate of any desired length or width and having a thickness from 0.1 to 10 cm. It is to be understood, that the foregoing structures may comprise a laminate of one or more layers of the same or different organic polymer, and include as well any other suitable material, such as wood, paper, metal, cloth, or oxides of one or more metal or metalloids, exemplified by clay, talc, silica, alumina, silicon nitride, or stone, as one or more layers of a multilayer structure or as a component of one or more layers, with the proviso that the exposed surface of the substrate comprise one or more organic polymers.

Highly desirably, the first layer (interchangeably herein referred to as an adhesive layer) is applied directly to the surface of the substrate to be coated, which may be washed or rinsed to remove foreign material from the surface, but desirably not surface modified by application of an intermediate layer such as a sputtered metal (metallization) and without treatment to alter surface properties such as use of corona discharge, uv-light, electron beam, ozone, oxygen, or other chemical or physical treatment to oxidize the surface in the absence of a silicon compound.

The invention is particularly adapted for use with substrates comprising homopolymers of an ester of (meth)acrylic acid, copolymers of more than one ester of (meth)acrylic acid, and copolymeric derivatives of the foregoing polymers additionally comprising one or more copolymerizable comonomers. Highly preferred esters of (meth)acrylic acid include the hydrocarbyl esters, especially alkyl esters, containing from 1 to 10 carbons, more preferably from 1 to 8 carbons in each ester group. Highly preferred esters include butylacrylate and methylmethacrylate. In addition, such polymers may include a copolymerizable comonomer, especially a divalent, cross-link forming comonomer (referred to as cross-linked, poly(meth)acrylate polymers). Examples especially include the di(meth)acrylate esters of dialcohols, especially alkylene glycols and poly(alkylene)glycols.

The foregoing crosslinked polymeric compositions preferably comprise hard segments or inhomogeneous regions, such as gels, formed by polymerization, including cross-link forming polymerizations, especially under biphasic polymerization conditions. One suitable example of such reaction conditions include polymerization by use of sequential, suspension or emulsion polymerization conditions to produce separate polymer segments having a difference in chemical or physical properties such that the resulting polymer lacks homogeneity. Such polymers are known in the art and commercially available. Examples include sequentially suspension polymerized cross-linked polymers of alkyl esters of acrylic and methacrylic acid. Such polymers can be produced by first reacting an alkyl ester of acrylic acid having an alkyl group containing 2 to 8 carbon atoms with 0.1 to 5 percent, preferably 0.5 to 1.5 percent, cross-linking monomer in an aqueous suspending medium. The cross-linking monomer is a bi- or polyfunctional compound with an ability to cross-link the alkyl acrylate. Suitable cross-linking monomers are alkylene glycol diacrylates such as ethylene glycol diacrylate and 1,3-butylene glycol diacrylate. In subsequent polymerization stages, increasing proportions of 1 to 4 carbon alkyl methacrylate are used, such that the resulting polymer contains inhomogeneous hard segmented regions. Suitable emulsifying agents and free radical initiators are used. Suitable polymers can also contain minor amounts of copolymerized acrylic and methacrylic acids. For example, a useful polymer can be a rubbery, cross-linked poly(alkyl acrylate) dispersed in a continuous phase of a predominantly methacrylate polymer, optionally containing minor amounts of acrylates, acrylic acid, or methacrylic acid copolymerized therewith. Such polymers are described further in U.S. Pat. Nos. 3,562,235, 3,812,205, 3,415,796, 3,654,069, and 3,473,99, and elsewhere.

In a preferred embodiment, the invention is used in a process where an abrasion resistant is applied to a film or sheet of the polymeric substrate before or after formation of a laminate with other polymeric materials. Preferably, such an abrasion resistant coating is applied as a final step in a cast or extrusion, sheet or film forming process. The coated product may be thereafter cut to size, formed into desired shapes in subsequent thermoforming or molding operations, or laminated to solid materials or substances without loss or degradation of the abrasion resistant coating.

The process equipment used to apply the abrasion resistant coating may be located in an inert environment, but preferably is operated under ambient atmospheric conditions. The process is operated at atmospheric pressure with sufficient volumetric flow of working gas or the use of seals, vacuum ports or other suitable means to reduce incursion of ambient gases leading to alteration of the working gas composition. Preferably, the volumetric flow of working gas (including organosilicon compound, carrier gas, oxidant and balance gas) is from 10 to 5,000 cc/minute per cm² of electrode surface.

Any suitable electrode geometry and reactor design can be employed in the present process. For thick substrates, such as sheet material, it may be desirable that both the electrode and the counter electrode be located on the same side of the substrate to be coated. Plasma created reaction products are impinged onto the surface of the substrate after passing by the electrodes. Exhaust ports from the reactor are located near the substrate surface and spatially removed from the electrodes to permit contact of the plasma or at least the reaction products formed therein with the substrate surface before exiting the reactor. If desired, the shape of the resulting corona discharge may be modified by the use of a magnetic field as previously disclosed in the art. For thinner substrates, the counter electrode may be a conductive surface upon which the target or substrate is supported or otherwise supported on the opposite side of the substrate from the electrode. Highly desirably, the electrode and counter electrode are encased in a porous nonconductive casing and oriented in close proximity to the substrate surface to be coated. Either the substrate or the entire counter electrode containing the substrate may be moving, especially in a continuous treating process.

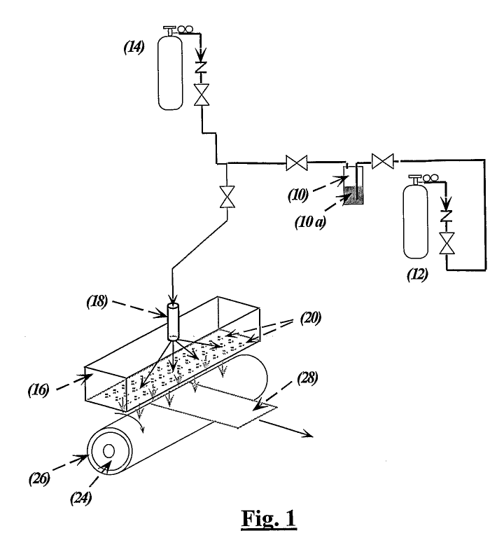

FIG. 1 provides an illustration of one apparatus used in carrying out the method of the present invention with a flexible film substrate. In FIG. 1, organosilicon reagent compound (10) is generated from the headspace of a contained volatile liquid (10a) of the organosilicon compound, carried by a carrier gas (12) from the headspace and merged with balance gas (14) before transport to the electrode (16). The carrier gas (12) and the balance gas (14) drive the organosilicon compound (10) through the electrode (16), more particularly, through at least one inlet (18) of electrode (16), and through outlets (20), which are typically in the form of slits or holes or the gaps between a plurality of conductive elements. Power is applied to the electrode (16) to create a glow discharge between the electrode (16) and the counter-electrode (24), which is optionally fitted with a dielectric layer (26). It is to be understood that the electrode (16) may also or alternatively be fitted with a dielectric sleeve (not shown in the figure). Substrate (28) is passed continuously along the dielectric layer (26) and coated with the polymeric siloxane or silicon oxide product. Alternately, the substrate, if flexible, may be attached to the rotating surface of the electrode.

It has been surprisingly discovered that a siloxane or silicon oxide coating that is powder-free or substantially powder-free and preferably an optically clear transparent coating, can be rapidly deposited onto the surface of the substrate using the process of the invention.

### EXAMPLES

The invention is further illustrated by the following example that should not be regarded as limiting of the present invention.

### Example 1

### Coating of Polycarbonate Substrate

A substrate is coated with a polymeric organosilicon film using the apparatus substantially as illustrated in FIG. 1. The electrodes and power supply are obtained from Corotec Industries, Farmington, Conn. The equipment is designed with a gas inlet above the discharge region which injects the working gas into a space between a vertically disposed electrode and counter electrode 10 cm in length located above a discharge zone at a pressure slightly above atmospheric (1.02 kPa). The power supply is adjusted to 900 W to provide a non-thermal arc discharge. The substrate is supported on circular counter electrode and is rotated beneath the discharge zone at a uniform rate. The entire apparatus is located in a normal atmospheric environment.

The substrate is polycarbonate film with a thickness of 7 mil (0.18 mm) which is washed with methanol to remove impurities but otherwise untreated. Vaporous tetraethoxyorthosilicate (TEOS) heated to 140° C. or tetramethyldisiloxane (TMDSO) at 20° C. at flow rates of 500 standard cm³/minute (sccm) is dispersed in a steam of a carrier gas (N₂) at 20° C. (for runs 1-4) and combined with a balance gas (air or N₂) at a flow rate of 30 standard ft³/minute (scfm) (8.5×10⁵ sccm). Additional oxidant (air or N₂O) is added (if used) at a flow rate of 5000 sccm. (In runs 5 and 6, TMDSO in N₂ carrier gas is dispersed directly into the oxidant without use of a balance gas). The overall gas velocity through the electrode to the substrate is adjusted to 8 m/s. The substrate is coated at a deposition rate selected to provide a uniform, smooth, optically clear coating. Steady state deposition rates (μm/minute) are determined after stable operation is reached. Results are contained in Table 1.

TABLE 1

| | | | | Deposition |
|---|---|---|---|---|
| Run | Silicon compound | Balance Gas | Oxidant | Rate (μm/min) |
| 1 | TEOS | air | — | 0.8 |
| 2 | ″ | N₂ | N₂O | 2.4 |
| 3 | TMDSO | air | — | 1.6 |
| 4 | ″ | N₂ | N₂O | 2.4 |
| 5 | ″ | — | air | 0.8 |
| 6 | ″ | — | N₂O | 14 |

As may be seen by reference to the results contained in Table 1, much faster deposition rates can be achieved while maintaining consistent film quality by use of N₂O oxidant compared to the use of air.

1. A process for depositing a layer of a plasma polymerized, organosiloxane, siloxane or silicon oxide onto the surface of an organic polymeric substrate by atmospheric pressure glow discharge deposition from a gaseous mixture comprising a silicon containing compound and an oxidant, characterized in that the oxidant comprises N₂O.

2. The process of claim 1 wherein the gaseous mixture is prepared by combining the silicon containing compound in a carrier gas which is then dispersed in a balance gas comprising an oxidant .

3. The process of claim 1 or 2 wherein the silicon containing compound is combined with nitrogen carrier gas and dispersed in a balance gas comprising air or nitrogen and further mixed with N₂O oxidant.

4. The process of any one of claims 1-3 wherein the silicon containing compound is an organosiloxane.

5. The process of claim 4 wherein the organosiloxane is tetramethyldisiloxane.
